(19) United States
(12) Patent Application Publication
(10) Pub. No.: US 2025/0224345 A1
(43) Pub. Date: Jul. 10, 2025

(54) WAFER INSPECTION APPARATUS AND WAFER INSPECTION SYSTEM INCLUDING THE SAME

(71) Applicant: SAMSUNG ELECTRONICS CO., LTD., Suwon-si (KR)

(72) Inventors: Jun Taek OH, Suwon-si (KR); Dong Gun LEE, Suwon-si (KR); Ki Hun KANG, Suwon-si (KR); Seung A LIM, Suwon-si (KR); Tae Joong KIM, Suwon-si (KR)

(73) Assignee: SAMSUNG ELECTRONICS CO., LTD., Suwon-si (KR)

(21) Appl. No.: 18/920,267

(22) Filed: Oct. 18, 2024

(30) Foreign Application Priority Data
Jan. 5, 2024 (KR) 10-2024-0001947

(51) Int. Cl. G01N 21/95

(52) U.S. Cl. CPC G01N 21/9501; G01N 2201/0635; G01N 2201/0636; G01N 2201/127

(57) ABSTRACT

A wafer inspection apparatus is provided. The wafer inspection apparatus includes a light source generating incident light, an input part slit passing some of the incident light, an input part condensing mirror focusing incident light that passes through the input part slit, a diffraction grating diffracting the incident light and spectrally dividing the incident light into monochromatic beams, an output part condensing mirror focusing the monochromatic beams and an output part slit passing some of the monochromatic beams.

### CROSS-REFERENCE TO RELATED APPLICATION

This application is based on and claims priority from Korean Patent Application No. 10-2024-0001947 filed on Jan. 5, 2024 in the Korean Intellectual Property Office, and all the benefits accruing therefrom under 35 U.S.C. 119, the contents of which in its entirety are herein incorporated by reference.

### BACKGROUND

### 1. Field

The disclosure relates to a wafer inspection apparatus and a wafer inspection system including the same, and more particularly, to a wafer inspection apparatus with high wavelength resolution for wafer inspection and a wafer inspection system including the wafer inspection apparatus.

### 2. Description of the Related Art

Recently, highly scaled, high-density semiconductor chips can be spaced with fine widths and fine pitches on a wafer. However, a wafer inspection process may be required for inspecting these semiconductor chips.

For example, the wafer inspection process may include utilizing monochromatic light with precise wavelengths for wafer inspection tasks. Therefore, research is being conducted on wafer inspection apparatuses with high wavelength resolution capable of generating monochromatic light with accurate wavelengths.

### SUMMARY

Aspects of the disclosure provide a wafer inspection apparatus with high wavelength resolution.

Aspects of the disclosure also provide a wafer inspection system with high wavelength resolution.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, there is provided a wafer inspection apparatus including: a first slit configured to pass a portion of incident light from a light source; a first condensing mirror configured to focus the portion of the incident light that passes through the first slit; a diffraction grating configured to diffract the portion of the incident light and spectrally divide the portion of the incident light into monochromatic beams; a second condensing mirror configured to focus the monochromatic beams; and a second slit configured to pass a first monochromatic beam, among the monochromatic beams for inspecting a wafer, wherein a first grating rotation angle of the diffraction grating for outputting the first monochromatic beam is set based on a grating equation, and wherein one or more calibration parameters of the grating equation is based on: detecting an i-th wavelength with a peak intensity in an i-th monochromatic beam based on an i-th rotation of the diffraction grating, where i is a natural number of 2 or greater, obtaining an i-th wavelength deviation based on a difference between a measured value for the i-th wavelength and a reference value for the i-th wavelength, the reference value for the i-th wavelength being a unique value of the light source, and calculating the one or more calibration parameters of the grating equation using a least squares method such that a sum of squares of deviations of the i-th wavelength from k=1 to n is minimized, where n is a natural number.

According to another aspect of the disclosure, there is provided a wafer inspection apparatus including: a housing; a light source provided outside the housing, the light source configured to generate incident light; a first slit provided inside the housing, the first slit configured to pass a portion of incident light from a light source; a first condensing mirror provided inside the housing, the first condensing mirror configured to focus the portion of the incident light that passes through the first slit; a diffraction grating provided inside the housing, the diffraction grating configured to diffract the portion of the incident light; a second condensing mirror provided inside the housing, the second condensing mirror configured to focus monochromatic beams spectrally divided from the incident light; a second slit provided inside the housing, the second slit configured to pass a portion of a first monochromatic beam, among the monochromatic beams for inspecting a wafer; and a processor configured to set a first grating rotation angle of the diffraction grating for outputting the first monochromatic beam based on a grating equation by: detecting an i-th wavelength with a peak intensity in an i-th monochromatic beam based on an i-th rotation of the diffraction grating, where i is a natural number of 2 or greater, obtaining an i-th wavelength deviation based on a difference between a measured value for the i-th wavelength and a reference value for the i-th wavelength, the reference value for the i-th wavelength being a unique value of the light source, and calculating one or more calibration parameters of the grating equation using a least squares method such that a sum of squares of deviations of the i-th wavelength from k=1 to n is minimized, where n is a natural number, wherein the incident light reaches the diffraction grating, sequentially passing through the light source, the first slit, and the first condensing mirror, wherein the incident light is spectrally divided into the monochromatic beams by being diffracted by the diffraction grating, and wherein the monochromatic beams are output outside the housing, sequentially passing through the second condensing mirror and the second slit,

According to another aspect of the disclosure, there is provided a wafer inspection system including: a wafer inspection apparatus configured to emit first monochromatic light; a collimator configured to collimate the first monochromatic light into parallel light; an imaging optical system configured to generate an image corresponding to second monochromatic light reflected from a wafer based on the parallel light; and an image sensor configured to analyze data from the image, wherein the wafer inspection apparatus includes: a first slit configured to pass a portion of incident light from a light source; a first condensing mirror configured to focus the portion of the incident light that passes through the first slit; a diffraction grating configured to diffract the portion of the incident light and spectrally divide the portion of the incident light into monochromatic beams; a second condensing mirror configured to focus the monochromatic beams; and a second slit configured to pass the first monochromatic beam, among the monochromatic beams for inspecting a wafer, wherein a first grating rotation angle of the diffraction grating for outputting the first monochromatic beam is set based on a grating equation, and wherein one or more calibration parameters of the grating equation is based on: detecting an i-th wavelength with a peak intensity in an i-th monochromatic beam based on an i-th rotation of the diffraction grating, where i is a natural number of 2 or greater, obtaining an i-th wavelength deviation based on a difference between a measured value for the i-th wavelength and a reference value for the i-th wavelength, the reference value for the i-th wavelength being a unique value of the light source, and calculating the one or more calibration parameters of the grating equation using a least squares method such that a sum of squares of deviations of the i-th wavelength from k=1 to n is minimized, where n is a natural number.

However, aspects of the disclosure are not restricted to those set forth herein. The above and other aspects of the disclosure will become more apparent to one of ordinary skill in the art to which the disclosure pertains by referencing the detailed description of the disclosure given below.

### BRIEF DESCRIPTION OF DRAWINGS

The above and other aspects and features of the disclosure will become more apparent by describing in detail example embodiments thereof with reference to the attached drawings, in which:

FIG. 1 is a schematic diagram illustrating a wafer inspection system including a wafer inspection apparatus according to an embodiment of the disclosure.

FIGS. 2 and 3 are schematic diagrams illustrating a wafer inspection apparatus according to an embodiment of the disclosure.

FIG. 4 is a graph showing the spectrum of incident light generated by a light source.

FIG. 5 is a graph showing the intensity of monochromatic light detected by the intensity detector.

FIG. 6 is a graph for explaining how to convert a rotational angle deviation into a wavelength deviation.

FIG. 7 illustrates how to calculate calibration parameters for a wafer inspection apparatus according to an embodiment of the disclosure.

FIG. 8 is a schematic diagram illustrating a wafer inspection apparatus according to an embodiment of the disclosure.

FIG. 9 illustrates graphs showing the resolution of a wafer inspection apparatus according to an embodiment of the disclosure, before and after the setting of calibration parameters.

FIG. 10 is a flowchart illustrating an operating method of a wafer inspection apparatus according to an embodiment of the disclosure.

FIG. 11 is a schematic drawing illustrating a wafer inspection apparatus according to an embodiment of the disclosure.

### DETAILED DESCRIPTION

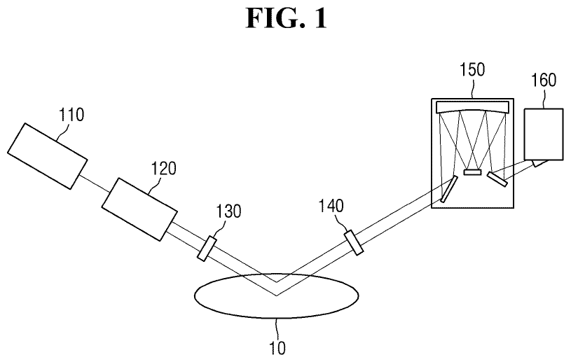

FIG. 1 is a schematic diagram illustrating a wafer inspection system including a wafer inspection apparatus according to an embodiment of the disclosure.

Referring to FIG. 1, the wafer inspection system according to an embodiment of the disclosure may include a wafer inspection apparatus 110, a collimator 120, a first polarizer 130, a second polarizer 140, an imaging optical system 150, and an image sensor 160.

The wafer inspection apparatus 110 may extract monochromatic light from light incident from a light source. The light emitted from the light source may be a mixture of various beams with different wavelengths. According to an embodiment, the wafer inspection apparatus 110 may extract only the monochromatic light that has a particular wavelength from among the various beams. The wafer inspection apparatus 110 may extract the monochromatic light at a specific granularity based on a resolution of the wafer inspection apparatus. For example, the higher the resolution of the wafer inspection apparatus 110, the wafer inspection apparatus 110 may more precisely extract the monochromatic light that has the particular specific wavelength from among the various beams.

The extraction of only the monochromatic light with the particular wavelength by the wafer inspection apparatus 110 may increase the precision of the inspection of a wafer 10.

The collimator 120 may include one or more mirrors, one or more lenses, or a combination including at least one lens and at least one mirror. The collimator 120 may collimate the monochromatic light incident from the wafer inspection apparatus 110 into parallel light. In this example case, diverging light may not be used for the inspection of the wafer 10. The collimator 120 may output the monochromatic light as parallel light suitable for the inspection of the wafer 10.

The first polarizer 130 may output polarized light at a particular angle from among parallel monochromatic beams incident from the collimator 120.

The parallel monochromatic light incident from the collimator 120 may be incident on the wafer 10 through the first polarizer 130.

The wafer 10 may include, but is not limited to, bulk silicon (Si) or Si-on-insulator (SOI). For example, the wafer 10 may be a Si wafer or may include other materials than Si, such as, for example, silicon germanium (SiGe), SiGe-on-insulator (SGOI), indium antimonide, lead telluride compounds, indium arsenide, indium phosphide, gallium arsenide, or gallium antimonide. However, the disclosure is not limited thereto, and as such according to another embodiment, the wafer may include another material.

The parallel monochromatic light incident on the wafer 10 may be reflected from the wafer 10.

The second polarizer 140 may output polarized light at a specific angle from among the monochromatic light reflected from the wafer 10. The specific angle may be predetermined.

The imaging optical system 150 may generate an optical image. For example, the imaging optical system 150 may generate a dot-shaped image or an image of a shape with a specific area. The specific area may be predetermined.

According to an embodiment, the imaging optical system 150 may include various mirrors or lenses configured to generate an image. Here, the various mirrors refer to mirrors with reflective surfaces of different curvatures, and the various lenses refer to lenses with refractive surfaces of different curvatures. For example, an image may be generated or created based on the arrangement of the various mirrors or lenses.

The monochromatic light passing through the second polarizer 140 may be incident on the imaging optical system 150.

The image sensor 160 may analyze the monochromatic light reflected from the wafer 10. The image sensor 160 may analyze the image created by the imaging optical system 150. The image sensor 160 may output the analyzed image as an electrical image signal. The image sensor 160 may be a charge-coupled device (CCD) image sensor, which transmits charge amount directly, or a complementary metal-oxide-semiconductor (CMOS) image sensor, which conveys the charge amount of each pixel as a digital signal, but the disclosure is not limited thereto.

The monochromatic light passing through the imaging optical system 150 may be incident on the image sensor 160.

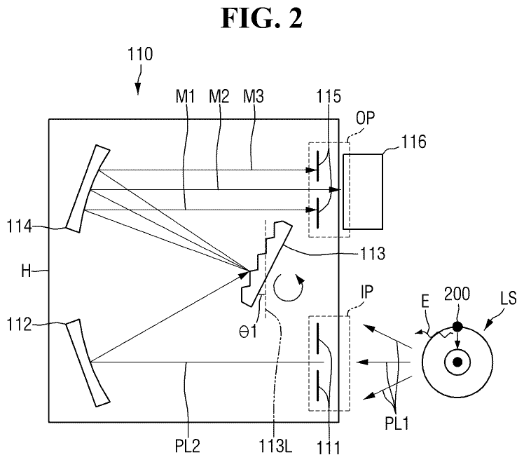

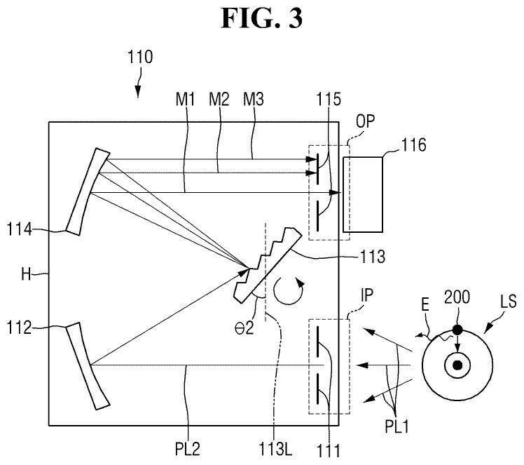

FIGS. 2 and 3 are schematic diagrams illustrating a wafer inspection apparatus according to an embodiment of the disclosure.

Referring to FIGS. 2 and 3, light may be emitted from a light source LS. The light emitted from the light source LS will hereinafter be referred to as first incident light PL1.

The first incident light PL1, emitted from the light source LS, may have monochromatic beams with various wavelengths mixed in the first incident light PL1. In this case, the monochromatic beams mixed in the first incident light PL1 may have discrete energies according to quantized energy levels.

In an example case in which the first incident light PL1 is spectrally analyzed, the first incident light PL1 may be separated into various monochromatic beams, each having a discrete energy E. The discrete energy E possessed by each of the monochromatic beams may be energy E emitted as an electron 200 moves from a higher energy level to a lower energy level. Each of the monochromatic beams may have the discrete energy E because of quantization of each energy level.

The first incident light PL1, emitted from the light source LS, may pass through a housing H. The first incident light PL1 may pass through an input part IP.

In an embodiment, the first incident light PL1 may pass through an empty space penetrating the surface of the housing H.

In an embodiment, the housing H may be transparent, and the first incident light PL1 may be able to pass through the housing H.

The first incident light PL1 that passes through the housing H may pass through an input part slit 111. According to an embodiment, the input part slit 111 may be a narrow gap formed by making two blades face each other to adjust the width of the first incident light PL1. However, the disclosure is not limited thereto, and as such, the input slit part 111 may be implemented in another manner according to another embodiment. According to an embodiment, only a portion of the first incident light PL1 may pass through the input part slit 111. For example, only some of the first incident light PL1 may pass through the input part slit 111.

The first incident light PL1 that passes through the input part slit 111 will hereinafter be referred to as second incident light PL2 for convenience. Therefore, the first incident light PL1 and the second incident light PL2 may be substantially the same.

The distance between the two blades that form the input part slit 111 may be fixed, narrowed, or widened. The distance between the two blades that form the input part slit 111 may be adjusted according to one or more characteristics of the first incident light PL1. For example, the distance between the two blades that form the input part slit 111 may be adjusted based on the wavelength of the first incident light PL1.

Although the input part slit 111 is depicted as being provided inside the housing H, the input part slit 111 may also be provided outside the housing H.

The second incident light PL2 may reach an input part condensing mirror 112. The second incident light PL2 may be reflected by the input part condensing mirror 112.

The input part condensing mirror 112 may be provided inside the housing H.

The input part condensing mirror 112 may focus the second incident light PL2. For example, the input part condensing mirror 112 may condense the second incident light PL2. The input part condensing mirror 112 may be a concave mirror. The input part condensing mirror 112 may be coated with a material with reflective properties. For example, the input part condensing mirror 112 may be coated with a material including, but not limited to, aluminum (Al).

The focusing power of the input part condensing mirror 112 may be significant. For example, the focusing power of the input part condensing mirror 112 may be greater than a reference value. For example, the degree to which light incident on the input part condensing mirror 112 converges to a single focal point may be significant.

Although the input part condensing mirror 112 is depicted as being a concave mirror, is shown, a convex lens may be used as the input part condensing mirror 112, according to another embodiment. Since a convex lens may also have a significant focusing power (e.g., greater than a reference value), a condensing lens, which is a convex lens, may be used instead of the input part condensing mirror 112, according to another embodiment.

The second incident light PL2, reflected from the input part condensing mirror 112, may reach a diffraction grating 113.

The diffraction grating 113 may be provided inside the housing H.

The diffraction grating 113 may diffract the second incident light PL2.

In an example case in which the second incident light PL2 is diffracted, the second incident light PL2, which is composed of various wavelengths, may be separated. The second incident light PL2 may be separated into a first monochromatic beam M1, a second monochromatic beam M2, and a third monochromatic beam M3. The second incident light PL2 is depicted in FIGS. 2 and 3 as being separated into three monochromatic beams (i.e., the first, second, and third monochromatic beams M1, M2, and M3), but the disclosure is not limited thereto. As such, according to another embodiment, the second incident light PL2 may be separated into more than three monochromatic beams.

The diffraction direction of the monochromatic beams generated by the diffraction of the second incident light PL2 (e.g., the first, second, and third monochromatic beams M1, M2, and M3) may vary depending on the arrangement of the diffraction grating 113 and the wavelength of the second incident light PL2. For example, the monochromatic beams generated by the diffraction of the second incident light PL2 may satisfy a diffraction grating equation.

The diffraction grating equation may Equation 1 below.

$$θ = {θ}_{z} + α * {sin}^{- 1} ( \frac{λ}{2 d cos K} ) \qquad [ Equation 1 ]$$

In Equation 1, θ may represent grating rotation angle. That is, the grating rotation angle θ may indicate the extent to which the diffraction grating 113 has rotated.

In Equation 1, θ_{z} may be a zeroth diffraction angle. For example, the zeroth diffraction angle θ_{z} may correspond to an angle at which light exits the diffraction grating 113 in the opposite direction to light incident on the diffraction angle 113, and at the same angle as the incident light.

In Equation 1, α may represent the slope of the angle increment. The angle increment slope a may vary for each diffraction grating 113 and may thus be a unique value for each diffraction grating 113.

In Equation 1, λ may represent wavelength. That is, the wavelength λ may vary for each monochromatic light included in the incident light and may be determined by the wavelength of the monochromatic light.

In Equation 1, d may represent the reciprocal of grating groove density. The grating groove density reciprocal d may vary for each diffraction grating 113 and may thus be a unique value for each diffraction grating 113.

In Equation 1, K may represent deviation angle. That is, the deviation angle K may indicate the angle between the light incident on the diffraction grating 113 and the light reflected from the diffraction grating 113.

According to an embodiment, calibration parameters corrected by the wafer inspection apparatus may include the angle increment slope a and the zeroth diffraction angle θ_{z}.

The first, second, and third monochromatic beams M1, M2, and M3, diffracted by the diffraction grating 113, may reach an output part condensing mirror 114. The first, second, and third monochromatic beams M1, M2, and M3 may be reflected by the output part condensing mirror 114.

The output part condensing mirror 114 may focus (or condense) monochromatic light (e.g., the first, second, and third monochromatic beams M1, M2, and M3). The output part condensing mirror 114 may be a concave mirror. The output part condensing mirror 114 may be coated with a material with reflective properties. For example, the output part condensing mirror 114 may be coated with a material, including but not limited to aluminum Al.

The output part condensing mirror 114 may be provided inside the housing H.

The focusing power of the output part condensing mirror 114 may be significant. For example, the focusing power of the output part condensing mirror 112 may be greater than a reference value. For example, the degree to which light incident on the output part condensing mirror 114 converges to a single focal point may be significant.

Although the output part condensing mirror 114 is depicted as being a concave mirror, a convex lens may also be used as the output part condensing mirror 114, according to another embodiment. Since a convex lens may also have a significant focusing power (e.g., greater than a reference value), a condensing lens, which is a convex lens, may be used instead of the output part condensing mirror 114, according to another embodiment.

The first, second, and third monochromatic beams M1, M2, and M3, reflected from the output part condensing mirror 114, may reach an output part slit 115. The output part slit 115 may be a narrow gap formed by making two blades face each other to adjust the width of the first, second, or third monochromatic beams M1, M2, or M3. According to an embodiment, only a portion of the first, second, and third monochromatic beams M1, M2, and M3 that reach the output part slit 115 may pass through the output part slit 115. For example, only some of the first, second, and third monochromatic beams M1, M2, and M3 that reach the output part slit 115 may pass through the output part slit 115.

The type of monochromatic light passing through the output part slit 115 may vary. For example, as illustrated in FIG. 2, the second monochromatic beam M2 may pass through the output part slit 115. According to another example, as illustrated in FIG. 3, the first monochromatic beam M1 may pass through the output part slit 115.

The type of monochromatic light passing through the output part slit 115 may vary depending on the rotation degree of the diffraction grating 113. For example, as illustrated in FIG. 2, in a case in which the diffraction grating 113 forms a first angle θ1 relative to an imaginary line 113L passing through the output part slit 115, the second monochromatic beam M2 may pass through the output part slit 115. On the other hand, as illustrated in FIG. 3, in an example case in which the diffraction grating 113 forms a second angle θ2 relative to the imaginary line 113L, the first monochromatic beam M1 may pass through the output part slit 115. The second angle θ2 may be greater than the first angle θ1.

The first and second angles θ1 and θ2, measured relative to the imaginary line 113L, are simply set to indicate the rotation degree of the diffraction grating 113. Therefore, the rotation angle θ in the diffraction grating equation does not necessarily have to be a measurement relative to the imaginary line 113L.

The output part slit 115 is depicted as being provided inside the housing H, but may also be provided outside the housing H.

The monochromatic light that passes through the output part slit 115 may pass through the housing H. The monochromatic light that passes through the output part slit 115 may also pass through an output part OP.

In an embodiment, monochromatic light may pass through the empty space penetrating the surface of the housing H.

In an embodiment, the housing H may be transparent, and thus, monochromatic light may be able to pass through the housing H.

The monochromatic light that passes through the housing H may reach an intensity detector 116. For example, as illustrated in FIG. 2, the second monochromatic beam M2 may pass through the housing H to reach the intensity detector 116. In another example, as illustrated in FIG. 3, the first monochromatic beam M1 may pass through the housing H to reach the intensity detector 116.

The intensity detector 116 may detect the intensity of the monochromatic light that passes through the housing H.

For the purpose of illustration, the term “monochromatic light” refers to light that has only one wavelength. However, since such light may not actually exist, the intensity of monochromatic light may be detected across a certain range of wavelengths. The intensity detector 116 may detect the intensity of light across the certain range of wavelengths.

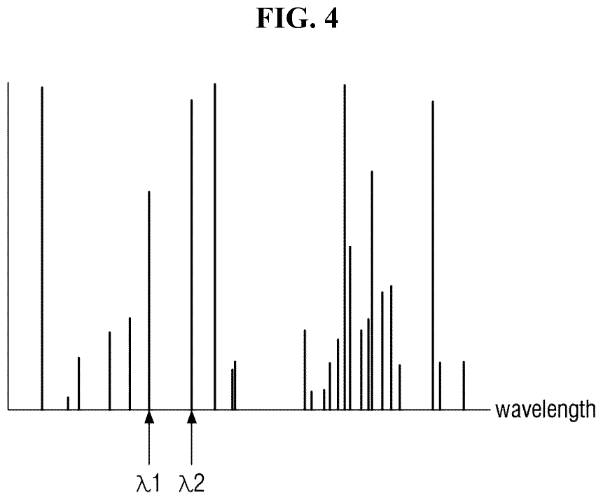

FIG. 4 is a graph showing the spectrum of incident light generated by a light source.

FIG. 4 illustrates the spectrum of incident light generated by a light source LS of FIG. 2 or FIG. 3. As previously mentioned, incident light emitted from the light source LS may have monochromatic light of various wavelengths mixed in the incident light, and monochromatic beams included in the incident light may have discrete energies according to quantized energy levels.

The characteristic of monochromatic beams having discrete energies according to quantized energy levels are as shown in FIG. 4. For example, referring to FIG. 4, first and second peaks appear at wavelengths λ1 and λ2, respectively, whereas no peaks appear between the wavelengths λ1 and λ2, indicating the absence of monochromatic light with wavelengths between the wavelengths λ1 and λ2. In other words, monochromatic light with an energy level between the energy corresponding to the wavelength λ1 and the energy corresponding to the wavelength λ2 is not included in the incident light emitted from the light source LS.

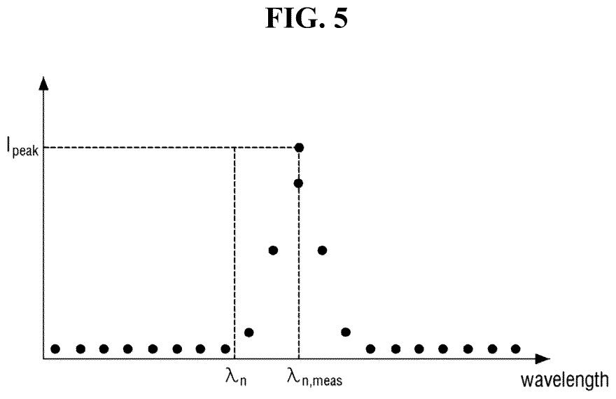

FIG. 5 is a graph showing the intensity of monochromatic light detected by the intensity detector.

Referring to FIG. 5, the intensity detector 116 may detect a peak intensity Iₚₑₐₖ. The peak intensity Iₚₑₐₖ refers to a highest intensity detected by the intensity detector 116. For example, in FIG. 5, the peak intensity Iₚₑₐₖ may be the highest intensity detected, and the wavelength corresponding to the peak intensity Iₚₑₐₖ may be a measured wavelength λ_{n,meas}. The intensity detector 116 may detect the measured wavelength λ_{n,meas}.

As previously mentioned, since light with only one wavelength does not exist, the intensity of monochromatic light may be detected across a certain range of wavelengths.

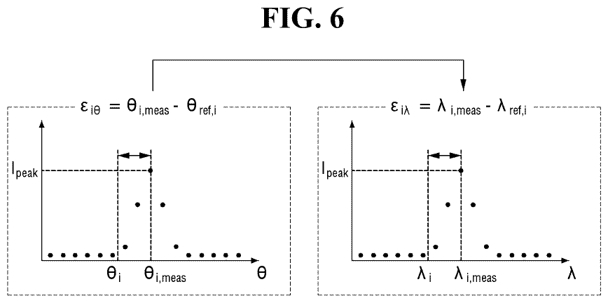

FIG. 6 is a graph for explaining how to convert a rotational angle deviation into a wavelength deviation.

Referring to FIG. 6, the intensity detector 116 may detect a measured grating rotation angle θ_{i,meas} corresponding to the peak intensity Iₚₑₐₖ.

A reference grating rotation angle θ_{ref,i} may be a value determined by the light source. That is, the reference grating rotation angle θ_{ref,i} may a unique value of the light source.

In an example case in which the wavelength of an i-th monochromatic beam contained in the light source is λj, the grating rotation angle of the diffraction grating 113 required to allow the i-th monochromatic beam to be detected through the output part slit 115 may be θᵢ.

Luminous intensity may be measured within a certain range including the grating rotation angle θᵢ. A measured grating rotation angle corresponding to the peak intensity Iₚₑₐₖ may be θ_{i,meas}.

A grating rotation angle deviation ε_{iθ} may be determined by the measured grating rotation angle θ_{i,meas} and a reference grating rotation angle θ_{ref,i}. For example, the grating rotation angle deviation ε_{iθ} may be the difference between the measured grating rotation angle θ_{i,meas} and the reference grating rotation angle θ_{ref,i}.

A measured wavelength λi,meas may be derived from the measured grating rotation angle θ_{i,meas}. That is, the intensity detector 116 may detect the measured wavelength λ_{i,meas}.

A reference wavelength λ_{ref,i} may be determined by the light source. That is, the reference wavelength λ_{ref,i} may be a unique value of the light source.

The grating rotation angle deviation ε_{iθ} may be converted into a wavelength deviation ε_{iλ}. The wavelength deviation ε_{iλ} may be the difference between the measured wavelength λ_{i,meas} and the reference wavelength λ_{ref,i}.

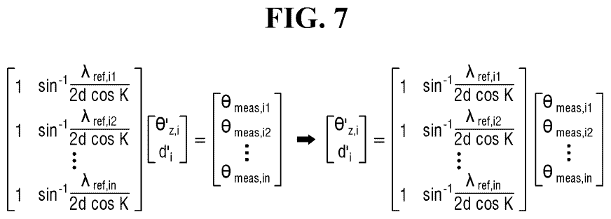

FIG. 7 illustrates how to calculate calibration parameters for a wafer inspection apparatus according to an embodiment of the disclosure.

Referring to FIG. 7, a zeroth diffraction angle and the slope of an angle increment may be calculated by a matrix.

The zeroth diffraction angle may be defined as θ′_{z,i}, and the angle increment slope may be a′ᵢ.

The reference wavelength for an n-th monochromatic beam may be defined as λ_{ref,in}.

Additionally, the reference grating diffraction angle for the n-th monochromatic beam may be defined as θ_{meas,in}, and the measured wavelength for the n-th monochromatic beam that corresponds to the reference grating diffraction angle θ_{meas,in} may be defined as λ_{meas,in}.

The reference wavelength λ_{meas,in}, the zeroth diffraction angle θ′_{z,i}, and the angle increment slope may be α′ᵢ are substituted into the diffraction grating equation, resulting in Equation 2 below.

$${θ}_{z , i}^{′} + {α}_{i}^{′} * {sin}^{- 1} ( \frac{{λ}_{r ef , i n}}{2 d cos K} ) = {θ}_{m e a s , i n} \qquad [ Equation 2 ]$$

It is assumed that there are n monochromatic beams, and by substituting the grating diffraction angle of each of the n monochromatic beams, n formulas may be obtained.

The n formulas may be as shown on the left side of FIG. 7. That is, the left side of the grating diffraction equation may be represented as the product of an n×2 matrix defined as

$$[ \begin{matrix}1 & {sin}^{- 1} & ( \frac{{λ}_{ref , i 1}}{2 d cos K} ) \\ ⋮ & & ⋮ \\ 1 & {sin}^{- 1} & ( \frac{{λ}_{ref , i n}}{2 d cos K} )\end{matrix} ]$$

and a 2×1 matrix defined as

$$[ \begin{matrix}{θ}_{z , i}^{′} \\ {α}_{i}^{′}\end{matrix} ] ,$$

and the right side of the grating diffraction equation may be n×1 matrix defined as

$$[ \begin{matrix}{θ}_{meas , i 1} \\ ⋮ \\ {θ}_{meas , i n}\end{matrix} ] .$$

Here, the n×2 matrix may be referred to as A.

Thus,

$$[ \begin{matrix}{θ}_{z , i}^{′} \\ {α}_{i}^{′}\end{matrix} ]$$

may be expressed as the product of A⁻¹ and

$$[ \begin{matrix}{θ}_{meas , i 1} \\ ⋮ \\ {θ}_{meas , i n}\end{matrix} ] .$$

The calibration parameters may be defined as θ′_{z,i} and α′ᵢ. Here, θ′_{z,i} and α′ᵢ may be derived by the least squares method. For example, the zeroth diffraction angle and the angle increment slope when Σₖ₌₁ⁿ|λ_{meas,ik}−λ_{ref,ik}|² is minimized may be θ′_{z,i} and α′ᵢ, respectively. Here, n is a natural number.

According to an embodiment, the intensity detector 116 may including a calibration calculation apparatus configured to obtain the calibration parameters for the wafer inspection apparatus. For example, the intensity detector 116 may include a memory storing one or more instructions, and a processor configured to execute the one or more instructions to control the wafer inspection apparatus and calculate the calibration parameters based on the operation of the wafer inspection apparatus. However, the disclosure is not limited thereto, and as such, the calibration calculation apparatus may be provided separately from the intensity detector 116.

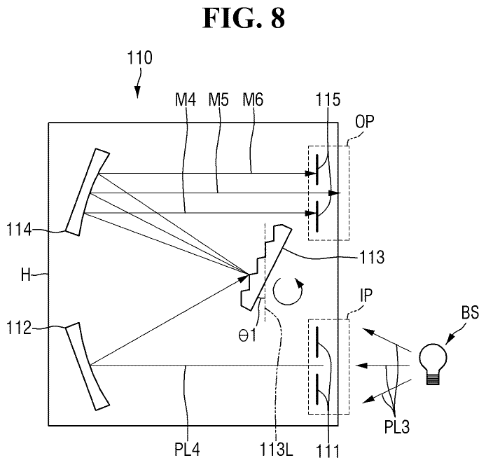

FIG. 8 is a schematic diagram illustrating a wafer inspection apparatus according to an embodiment of the disclosure. For convenience, the embodiment of FIG. 8 will hereinafter be described, focusing mainly on the differences from the embodiment of FIG. 2 or FIG. 3.

Referring to FIG. 8, a broadband light source BS may be provided.

The broadband light source BS may be different from the light source LS in FIG. 2 or FIG. 3. For example, while monochromatic light with discrete energies may be emitted from the light source LS, light with a continuous energy spectrum may be emitted from the broadband light source BS.

A wafer inspection apparatus 110 may be set to have θ″_{z} and α″ as calibration parameters. That is, a diffraction grating 113 of the wafer inspection apparatus 110 may be adjusted to a position and angle corresponding to θ″_{z} and α″, respectively, to have θ″_{z} and α″ as calibration parameters.

Light may be emitted from the broadband light source BS. The light emitted from the broadband light source BS will hereinafter be referred to as third incident light PL3.

The third incident light PL3, emitted from the broadband light source BS, may have beams of various wavelengths mixed therein. In this case, the beams mixed in the third incident light PL3 may have continuous energies.

The third incident light PL3, emitted from the broadband light source BS, may pass through a housing H. The third incident light PL3 may also pass through an input part IP.

In an embodiment, the third incident light PL3 may pass through an empty space penetrating the surface of the housing H.

In an embodiment, the housing H may be transparent, and thus, the third incident light PL3 may pass through the housing H.

The third incident light PL3 that passes through the housing H may also pass through an input part slit 111. The input part slit 111 may be a narrow gap formed by making two blades face each other to adjust the width of the third incident light PL3. According to an embodiment, only a portion of the third incident light PL3 may pass through the input part slit 111. For example, only some of the third incident light PL3 may pass through the input part slit 111.

The third incident light PL3 that passes through the input part slit 111 will hereinafter be referred to as fourth incident light PL4 for convenience.

Therefore, the third incident light PL3 and the fourth incident light PLA may be substantially the same.

The fourth incident light PL4 may be spectrally divided into fourth monochromatic light M4, fifth monochromatic light M5, and sixth monochromatic light M6 after passing through an input part condensing mirror 112 and the diffraction grating 113. The fourth monochromatic light M4, the fifth monochromatic light M5, and the sixth monochromatic light M6 may then be directed toward an output part slit 115 through an output part condensing mirror 114. According to an embodiment, only a portion of the fourth monochromatic light M4, the fifth monochromatic light M5, and the sixth monochromatic light M6 may pass through the output part slit 115. For example, only some of the fourth monochromatic light M4, the fifth monochromatic light M5, and the sixth monochromatic light M6 may pass through the output part slit 115. For convenience, the fourth incident light PLA is depicted as being spectrally divided into three monochromatic beams, but the number of spectrally divided monochromatic beams is not limited thereto.

The monochromatic light that passes through the output part slit 115 may pass through the housing H. The monochromatic light that passes through the output part slit 115 may also pass through an output part OP.

According to an embodiment, only the fifth monochromatic light M5 may pass through the output part slit 115. FIG. 8 illustrates only the fifth monochromatic light M5 as passing through the output part slit 115, but the disclosure is not limited thereto. For example, by adjusting the position and angle of the diffraction grating 113, the fourth monochromatic light M4 may be made to pass through the output part slit 115. Similarly, by adjusting the position and angle of the diffraction grating 113, the sixth monochromatic light M6 may be made to pass through the output part slit 115.

The fourth monochromatic light M4, the fifth monochromatic light M5, and the sixth monochromatic light M6 of FIG. 8 may be monochromatic light that have been more precisely extracted than the first, second, and third monochromatic beams M1, M2, and M3 of FIGS. 2 and 3.

The wafer inspection apparatus 110 using θ″_{z} and α″ as calibration parameters may have a high wavelength resolution. Therefore, the wafer inspection apparatus 110 using θ″_{z} and α″ may precisely extract only target monochromatic light from light generated by a light source (e.g., the broadband light source BS).

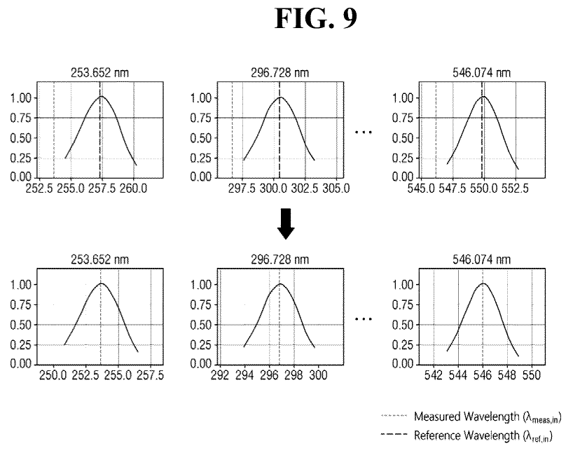

FIG. 9 illustrates graphs showing the resolution of a wafer inspection apparatus according to an embodiment of the disclosure, before and after the setting of calibration parameters.

Referring to FIG. 9, the top three graphs show the resolution before the setting of the calibration parameters, while the bottom three graphs show the resolution after the setting of the calibration parameters. The horizontal and vertical axes of each of these graphs represent wavelength and intensity, respectively.

To compare the resolution before and after the setting of the calibration parameters, monochromatic beams with known wavelengths were used. The wavelengths of these monochromatic beams are 253.652 nm, 296.728 nm, and 546.074 nm.

The graphs placed on the left are for monochromatic beam with a wavelength of 253.652 nm, the graphs in the middle are for monochromatic light with a wavelength of 296.728 nm, and the graphs on the right are for monochromatic light with a wavelength of 546.074 nm.

A higher resolution implies that a measured wavelength λ_{meas,in} of peak intensities is closer to the reference wavelength λ_{ref,in}. In FIG. 9, the bottom three graphs show a closer measured wavelength λ_{meas,in} of the peak intensities to the known reference wavelength λ_{ref,in}, compared to the top three graphs. Therefore, it may be observed that the resolution after the setting of the calibration parameters has improved compared to the resolution before the calibration parameters were set.

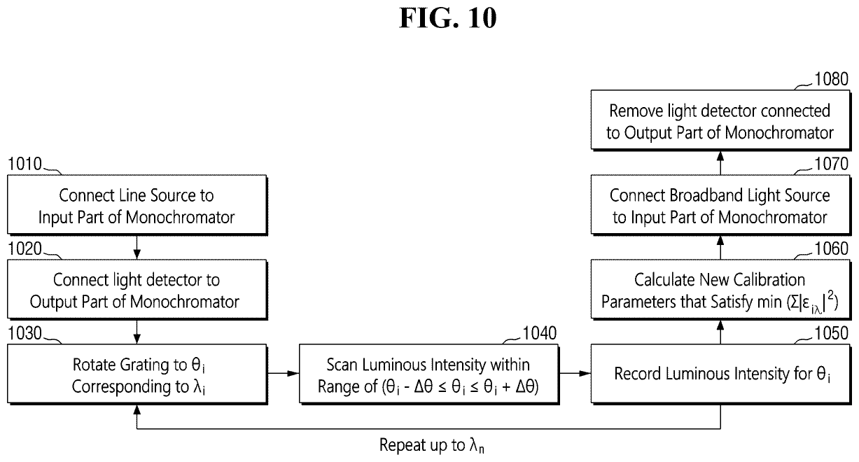

FIG. 10 is a flowchart illustrating an operating method of a wafer inspection apparatus according to an embodiment of the disclosure. The necessary components for the operation of the wafer inspection apparatus 110 are depicted in FIGS. 2, 3, and 8.

Referring to FIG. 10, in operation 1010, the method may include connecting the light source LS to the input part IP of a monochromator.

In operation 1020, the method may include connecting the intensity detector 116 to the output part OP of the monochromator.

In an example case in which the light source LS operates, incident light may be emitted from the monochromator. The incident light may contain monochromatic beams of various wavelengths. Among the monochromatic beams, an i-th monochromatic beam may have the wavelength λᵢ.

In operation 1030, the method may include rotating the diffraction grating 113 to an angle θᵢ corresponding to the wavelength λᵢ. In this case, only the monochromatic beam with the wavelength λᵢ may pass through the output part OP.

In operation 1040, the method may include scanning, by intensity detector 116, luminous intensity within the range of (θᵢ−Δθ≤θᵢ≤θᵢ+Δθ). In other words, the intensity detector 116 may scan luminous intensity within a specific range including the angle θᵢ.

In operation 1050, the method may include recording the luminous intensity for the angle θᵢ. An example graph showing the recorded luminous intensity for the angle θᵢ is as illustrated on the left side of FIG. 6.

According to an embodiment, the aforementioned operations 1010, 1020, 1030, 1040 and 1050 may be repeated up to a wavelength λₙ. That is, in an example case in which the incident light includes n monochromatic beams, the aforementioned operations 1010, 1020, 1030, 1040 and 1050 may be repeated for wavelengths λ₁ through λₙ. Here, n may be the maximum number of monochromatic beams that the light source LS may emit. In other words, n may be the maximum number of monochromatic beams contained in the incident light emitted by the light source LS. By repeating the aforementioned steps up to the wavelength λₙ, the measured wavelength λ_{i,meas} for each peak intensity may be detected.

In operation 1060, the method may include calculating new calibration parameters using the measured wavelength λ_{i,meas} and a reference wavelength λ_{i,ref} (λ_{ref,i}?). New calibration parameters that minimize Σ|ε_{iλ}|² may be calculated using the least squares method. That is, new calibration parameters that minimize Σᵢ₌₁ⁿ|λ_{i,meas}−λ_{i,ref}|² may be calculated using the least squares method. The reference wavelength λ_{i,ref} may be a wavelength value corresponding to the i-th monochromatic beam with the wavelength λ₁. The reference wavelength λ_{i,ref} may be a unique value of the light source.

The new calibration parameters may be an angle increment slope and a zeroth diffraction angle that minimize Σᵢ₌₁ⁿ|λ_{i,meas}−λ_{i,ref} |².

According to an embodiment, the method may include setting the new calibration parameters in the wafer inspection apparatus 110.

In operation 1070, the method may include connecting the broadband light source BS to the input part IP.

In operation 1080, the method may include removing the light detector 116 from the output part OP.

The broadband light source BS may emit light with continuous energy.

With the new calibration parameters set, the wafer inspection apparatus 110 may have improved resolution. Thus, monochromatic light with a specific wavelength may be precisely extracted from the light with continuous energy emitted by the broadband light source BS.

The extracted monochromatic light with the specific wavelength may be used for inspecting the wafer 10.

According to an embodiment, the operation method illustrated in FIG. 10 may be performed by a controller or a processor. Moreover, a calibration calculation apparatus may be provided to obtain the calibration parameters for the wafer inspection apparatus. For example, the calibration calculation apparatus may include a memory storing one or more instructions, and a processor configured to execute the one or more instructions to control the wafer inspection apparatus and calculate the calibration parameters based on the operation of the wafer inspection apparatus. According to an embodiment, the calibration calculation apparatus may be provided in the intensity detector 116.

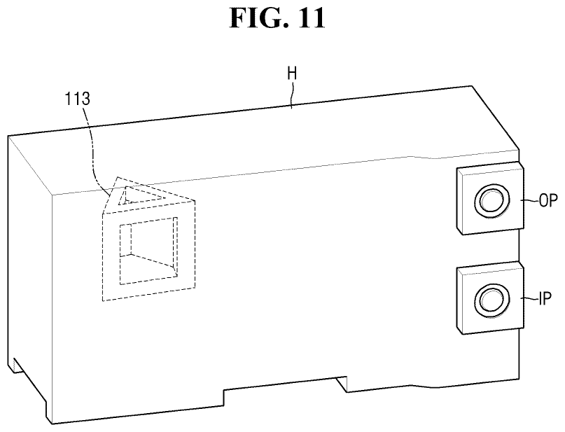

FIG. 11 is a schematic drawing illustrating a wafer inspection apparatus according to an embodiment of the disclosure.

Referring to FIG. 11, a wafer inspection device 110 may include an input part IP, a diffraction grating 113, an output part OP, and a housing H.

The housing H may be hollow.

The input part IP and the output part OP may be formed on one sidewall of the housing H.

The output part OP may be provided above the input part IP, and the input part IP may be provided below the output part OP. The positions of the output part OP and the input part IP are not limited to those illustrated in FIG. 11. For example, the input part IP may be provided above the output part OP.

Light may be supplied to the input part IP through an optical fiber.

According to an embodiment, an input part condensing mirror 112 may be provided inside the housing H to properly adjust the path of the light.

Light introduced through the optical fiber may reach the diffraction grating 113 via an input part condensing mirror 112.

The diffraction grating 113 may diffract the light.

According to an embodiment, an output part condensing mirror 114 may be provided inside the housing H to properly adjust the path of the light.

The light diffracted by the diffraction grating 113 may reach the output part OP via an output part condensing mirror 114.

Light may be emitted from the output part OP through the optical fiber.

In an example case in which calibration parameters are derived, a light source LS may be provided on the input part IP, and an intensity detector 116 may be provided on the output part OP.

In an example case in which a wafer 10 is inspected, a broadband light source BS may be provided on the input part IP. In an example case in which calibration parameters are derived, no element may be provided on the output part OP.

Those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A wafer inspection apparatus comprising:
a first slit configured to pass a portion of incident light from a light source;
a first condensing mirror configured to focus the portion of the incident light that passes through the first slit;
a diffraction grating configured to diffract the portion of the incident light and spectrally divide the portion of the incident light into monochromatic beams;
a second condensing mirror configured to focus the monochromatic beams; and
a second slit configured to pass a first monochromatic beam, among the monochromatic beams for inspecting a wafer, wherein a first grating rotation angle of the diffraction grating for outputting the first monochromatic beam is set based on a grating equation, and
wherein one or more calibration parameters of the grating equation is based on:
detecting an i-th wavelength with a peak intensity in an i-th monochromatic beam based on an i-th rotation of the diffraction grating, where i is a natural number of 2 or greater,
obtaining an i-th wavelength deviation based on a difference between a measured value for the i-th wavelength and a reference value for the i-th wavelength, the reference value for the i-th wavelength being a unique value of the light source, and
calculating the one or more calibration parameters of the grating equation using a least squares method such that a sum of squares of deviations of the i-th wavelength from k=1 to n is minimized, where n is a natural number.

2. The wafer inspection apparatus of claim 1, wherein
the grating equation is as follows:
$$θ = {θ}_{z} + α * {sin}^{- 1} ( \frac{λ}{2 d cos K} )$$
where θ represents the first grating rotation angle, θ_{z} represents a zeroth diffraction angle, a represents a slope of an angle increment, d represents a reciprocal of grating groove density, K represents deviation angle, and λ represents wavelength, and
the one or more calibration parameters comprise α and θ_{z}.

3. The wafer inspection apparatus of claim 2, wherein the one or more calibration parameters of the grating equation is further based on:
detecting measured values for first through n-th grating rotation angles for a first wavelength with a peak intensity in each of first through n-th monochromatic beams, and
obtaining an i-th grating rotation angle deviation based on a difference between a measured value for i-th grating rotation angle and a reference value for i-th grating rotation angle,
wherein the reference value for the i-th grating rotation angle is a unique value of the light source, and
wherein the i-th grating rotation angle deviation is converted into the i-th wavelength deviation.

4. The wafer inspection apparatus of claim 1, further comprises an intensity detector configured to measure luminous intensity within a range including the measured value for the i-th wavelength.

5. The wafer inspection apparatus of claim 1, wherein the light source comprises a broadband light source for calculating the one or more calibration parameters, the light source configured to emit light comprising the monochromatic beams, and the monochromatic beams have quantized energies.

6. The wafer inspection apparatus of claim 5, wherein
the monochromatic beams are distinguished based on magnitudes of the quantized energies of the monochromatic beams, and
n represents a number of monochromatic beams included in the incident light.

7. The wafer inspection apparatus of claim 1, wherein
the light source comprises a broadband light source for inspecting the wafer, the broadband light source configured to emit light comprising the monochromatic beams, and
wherein the monochromatic beams have continuous energies.

8. A wafer inspection apparatus comprising:
a housing;
a light source provided outside the housing, the light source configured to generate incident light;
a first slit provided inside the housing, the first slit configured to pass a portion of incident light from a light source;
a first condensing mirror provided inside the housing, the first condensing mirror configured to focus the portion of the incident light that passes through the first slit;
a diffraction grating provided inside the housing, the diffraction grating configured to diffract the portion of the incident light;
a second condensing mirror provided inside the housing, the second condensing mirror configured to focus monochromatic beams spectrally divided from the incident light;
a second slit provided inside the housing, the second slit configured to pass a portion of a first monochromatic beam, among the monochromatic beams for inspecting a wafer; and a processor configured to set a first grating rotation angle of the diffraction grating for outputting the first monochromatic beam based on a grating equation by:
detecting an i-th wavelength with a peak intensity in an i-th monochromatic beam based on an i-th rotation of the diffraction grating, where i is a natural number of 2 or greater,
obtaining an i-th wavelength deviation based on a difference between a measured value for the i-th wavelength and a reference value for the i-th wavelength, the reference value for the i-th wavelength being a unique value of the light source, and
calculating one or more calibration parameters of the grating equation using a least squares method such that a sum of squares of deviations of the i-th wavelength from k=1 to n is minimized, where n is a natural number,
wherein the incident light reaches the diffraction grating, sequentially passing through the light source, the first slit, and the first condensing mirror,
wherein the incident light is spectrally divided into the monochromatic beams by being diffracted by the diffraction grating, and
wherein the monochromatic beams are output outside the housing, sequentially passing through the second condensing mirror and the second slit.

9. The wafer inspection apparatus of claim 8, wherein
the grating equation is as follows:
$$θ = {θ}_{z} + α * {sin}^{- 1} ( \frac{λ}{2 d cos K} )$$
where θ represents the first grating rotation angle, θ_{z} represents a zeroth diffraction angle, α represents a slope of an angle increment, d represents a reciprocal of grating groove density, K represents deviation angle, and λ represents wavelength, and
the one or more calibration parameters comprise α and θ_{z}.

10. The wafer inspection apparatus of claim 9, wherein the processor is further configured to calculate the one or more calibration parameters of the grating equation by:
detecting measured values for first through n-th grating rotation angles for a first wavelength with a peak intensity in each of first through n-th monochromatic beams, and
obtaining an i-th grating rotation angle deviation based on a difference between a measured value for i-th grating rotation angle and a reference value for i-th grating rotation angle,
wherein the reference value for the i-th grating rotation angle is a unique value of the light source, and
wherein the i-th grating rotation angle deviation is converted into the i-th wavelength deviation.

11. The wafer inspection apparatus of claim 8, further comprises an intensity detector configured to measure luminous intensity within a range including the measured value for the i-th wavelength.

12. The wafer inspection apparatus of claim 8, wherein the light source comprises a broadband light source for calculating the one or more calibration parameters, the light source configured to emit light comprising the monochromatic beams, and the monochromatic beams have quantized energies.

13. The wafer inspection apparatus of claim 12, wherein
the monochromatic beams are distinguished based on magnitudes of the quantized energies of the monochromatic beams, and
n represents a number of monochromatic beams included in the incident light.

14. The wafer inspection apparatus of claim 8, wherein
the light source comprises a broadband light source for inspecting the wafer, the broadband light source configured to emit light comprising the monochromatic beams, and
wherein the monochromatic beams have continuous energies.

15. A wafer inspection system comprising:
a wafer inspection apparatus configured to emit first monochromatic light;
a collimator configured to collimate the first monochromatic light into parallel light;
an imaging optical system configured to generate an image corresponding to second monochromatic light reflected from a wafer based on the parallel light; and
an image sensor configured to analyze data from the image,
wherein
the wafer inspection apparatus comprises:
a first slit configured to pass a portion of incident light from a light source;
a first condensing mirror configured to focus the portion of the incident light that passes through the first slit;
a diffraction grating configured to diffract the portion of the incident light and spectrally divide the portion of the incident light into monochromatic beams;
a second condensing mirror configured to focus the monochromatic beams; and
a second slit configured to pass the first monochromatic beam, among the monochromatic beams for inspecting a wafer, wherein a first grating rotation angle of the diffraction grating for outputting the first monochromatic beam is set based on a grating equation, and
wherein one or more calibration parameters of the grating equation is based on:
detecting an i-th wavelength with a peak intensity in an i-th monochromatic beam based on an i-th rotation of the diffraction grating, where i is a natural number of 2 or greater,
obtaining an i-th wavelength deviation based on a difference between a measured value for the i-th wavelength and a reference value for the i-th wavelength, the reference value for the i-th wavelength being a unique value of the light source, and
calculating the one or more calibration parameters of the grating equation using a least squares method such that a sum of squares of deviations of the i-th wavelength from k=1 t on is minimized, where n is a natural number.

16. The wafer inspection system of claim 15, wherein
the grating equation is as follows:
$$θ = {θ}_{z} + α * {sin}^{- 1} ( \frac{λ}{2 d cos K} )$$
where θ represents the first grating rotation angle, θ_{z} represents a zeroth diffraction angle, α represents a slope of an angle increment, d represents a reciprocal of grating groove density, K represents deviation angle, and λ represents wavelength, and
the one or more calibration parameters comprise α and θ_{z}.

17. The wafer inspection system of claim 15, further comprises an intensity detector configured to measure luminous intensity within a range including the measured value for the i-th wavelength.

18. The wafer inspection system of claim 15, wherein the light source comprises a broadband light source for calculating the one or more calibration parameters, the light source configured to emit light comprising the monochromatic beams, and the monochromatic beams have quantized energies.

19. The wafer inspection system of claim 18, wherein
the monochromatic beams are distinguished based on magnitudes of the quantized energies of the monochromatic beams, and
n represents a number of monochromatic beams included in the incident light.

20. The wafer inspection system of claim 15, wherein
the light source comprises a broadband light source for inspecting the wafer, the broadband light source configured to emit light comprising the monochromatic beams, and
wherein the monochromatic beams have continuous energies.
